(19) United States
(12) Patent Application Publication
(10) Pub. No.: US 2009/0311500 A1
(43) Pub. Date: Dec. 17, 2009

(54) Deposition of Ruthenium Oxide Coatings on a Substrate

(75) Inventors: Liang Ye, Merseyside (GB); Michael P. Remington, JR., Toledo, OH (US)

Correspondence Address: MARSHALL & MELHORN, LLC, FOUR SEAGATE - EIGHTH FLOOR, TOLEDO, OH, 43604, US

(73) Assignees: PILKINGTON NORTH AMERICA, INC., Toledo, OH (US); PILKINGTON GROUP LIMITED, St. Helens, Merseyside (GB)

(21) Appl. No.: 12/085,211

(22) PCT Filed: Nov. 21, 2006
(86) PCT No.: PCT/US2006/044955

§ 371 Date: Feb. 24, 2009

Related U.S. Application Data
(60) Provisional application No. 60/739,483, filed on Nov. 23, 2005.

(51) Int. Cl. B32B 17/06; C23C 16/40

(52) U.S. Cl. 428/220; 427/248.1; 427/255.23; 427/255.19

(57) ABSTRACT

A CVD process is defined for producing a ruthenium dioxide or ruthenium metal like coating on an article. The article is preferably for use as an architectural glazing, and preferably has low emissivity and solar control properties. The method includes providing a heated glass substrate having a surface on which the coating is to be deposited. A ruthenium containing precursor, an oxygen containing compound, and optionally water vapor, in conjunction with an inert carrier gas, are directed toward and along the surface to be coated and the ruthenium containing precursor and the oxygen containing compound are reacted at or near the surface of the glass substrate to form a ruthenium dioxide coating.

### BACKGROUND OF THE INVENTION

1. Field of the Invention

The present invention relates to a chemical vapor deposition (CVD) method for producing a coated article, particularly coated architectural glass, and to the coated article so produced. Specifically, the invention relates to an improved method for producing a glass article coated with a layer of ruthenium oxide (RuₓO_{y}), preferably ruthenium dioxide (RuO₂), or a ruthenium metal like layer (ruthenium sub oxide layer), and the coated glass articles formed thereby.

2. Summary of Related Art

Known processes for producing coated glass articles can yield coated glass articles with varying properties, which can be selected for various applications. Coatings on architectural glass are commonly utilized to provide specific energy absorption and light transmittance properties. Additionally, coatings provide desired reflective or spectral properties that are aesthetically pleasing. The coated articles are often used singularly or in combination with other coated articles to form a glazing or window unit.

Coated glass articles are typically produced “on-line” by continuously coating a glass substrate while it is being manufactured in a process known in the art as the “float glass process.” Additionally, coated glass articles are produced “off-line” through a sputtering process. The former process involves casting glass onto a molten tin bath which is suitably enclosed, thereafter transferring the glass, after it is sufficiently cooled, to lift out rolls which are aligned with the bath, and finally cooling the glass as it advances across the rolls, initially through a lehr and thereafter while exposed to the ambient atmosphere. A non-oxidizing atmosphere is maintained in the float portion of the process, while the glass is in contact with the molten tin bath, to prevent oxidation of tin. An oxidizing atmosphere is maintained in the lehr. In general, the coatings are applied onto the glass substrate in the float bath of the float bath process. However, coatings may also be applied onto the substrate in the lehr, or in the lehr gap.

The attributes of the resulting coated glass substrate are dependent upon the specific coatings applied during the float glass process or an off-line sputtering process. The coating compositions and thicknesses impart energy absorption and light transmittance properties within the coated article while also affecting the spectral properties. Desired attributes may be obtainable by adjusting the compositions or thicknesses of the coating layer or layers. However, adjustments to enhance a specific property can adversely impact other transmittance or spectral properties of the coated glass article. Obtaining desired spectral properties is often difficult when trying to combine specific energy absorption and light transmittance properties in a coated glass article.

One common attribute of glass coatings is what is known in the art as low emissivity or “low E” glass, which has a coating of relatively high conductivity. Additionally, solar control properties controlling the transmission of solar energy can be an important feature of certain applications. Commonly, low emissivity and solar control glass is achieved in an on-line process by providing a doped tin oxide coating on the glass, with the most common dopants being fluorine and/or antimony. Different coating materials or combinations of materials and dopants can be selected to produce the desired properties on the glass. For example, silver based coatings are typically used in off-line processes.

A significant drawback to the currently known CVD of low emissivity, solar control coatings is the achievable carrier concentration of the tin oxide in the production process. Because of these limitations, the tin oxide coatings deposited on the glass must be relatively thick, generally on the order of 2500-3000 Å to achieve the desired properties. Additionally, in order to achieve the desired low emissivity and solar control properties, it may be necessary to deposit multiple layers with different dopants, e.g. a fluorine doped tin oxide layer and an antimony doped tin oxide layer.

### SUMMARY OF THE INVENTION

A method is defined for producing a relatively thin low emissivity, solar control layer on an article. The method involves the deposition of a ruthenium metal like or a ruthenium oxide coating on a glass article, preferably by CVD. Preferably, the application of the coating is done by an atmospheric pressure chemical vapor deposition process (APCVD). The coated glass article is preferably for use as an architectural glazing, having low emissivity and solar control properties.

As used herein, the term “ruthenium metal like” coating or layer indicates a layer of ruthenium containing trace amounts of oxygen in a non-stoichiometric ratio, i.e. (RuₓO_{y}), wherein x=1 and y is less than 1, preferably much less than 1. This can also be termed a “ruthenium sub oxide.” As used herein, the term “ruthenium oxide coating” means a coating comprising primarily ruthenium oxide in a stoichiometric ratio, i.e. (RuₓO_{y}), wherein x=1 and y=1, or preferably, ruthenium dioxide (RuO₂), and possibly containing other elements in trace amounts. It has been found that the non-stoichiometric ruthenium metal-like coating can exhibit increased conductivity compared to the ruthenium dioxide coating.

The method includes providing a heated glass substrate having a surface on which the coating is to be deposited. A ruthenium containing precursor along with an oxygen containing compound (typically an oxidant) and a carrier gas are utilized for the deposition of the ruthenium oxide coating. Water may additionally be added to the precursor mixture. The ruthenium containing precursor and an oxygen containing compound are directed toward and along the surface to be coated, and the ruthenium containing precursor and the oxygen containing compound are reacted at or near the surface of the glass substrate to form a ruthenium oxide or ruthenium metal like coating. The reaction preferably takes place in an on-line, float glass production process, preferably in the tin bath.

### DETAILED DESCRIPTION OF THE PREFERRED EMBODIMENT

In accordance with the present invention, there is provided a method for the deposition of a ruthenium oxide layer on a substrate, and the deposition of a ruthenium metal-like layer on a substrate, particularly a glass substrate. Specifically, the invention relates to the atmospheric pressure chemical vapor deposition of a ruthenium metal-like layer or a ruthenium dioxide layer from a combination of a ruthenium containing precursor and an oxygen containing compound. An inert carrier gas is combined with the ruthenium containing precursor and the oxygen containing compound for delivery to the coater. Additionally, within the scope of the present invention, it is also possible that water can be an additional precursor used in conjunction with the other precursors.

The preferred oxygen containing compound for use in the present invention is oxygen gas. Other oxygen containing compounds may be suitable for use in the present invention, but oxygen gas is preferred for its availability and ease of use. Multiple ruthenium containing precursors are available and suitable for use in the present invention. Preferably, the ruthenium containing precursor is one of ruthenium carbonyl (Ru₃(CO)₁₂), ruthenocene (Ru(C₅H₅)₂), ruthenium tris(tetramethylheptanedionate) (Ru(tmhd)₃), and bis(2,2,6,6-tetramethyl-3,5-heptanedionato)(1,5-cyclooctadiene)ruthenium[(C₁₁-H₁₉O₂)₂(C₈H₁₂)Ru]. Best results have been obtained through the use of ruthenocene as the ruthenium containing precursor, in terms of precursor delivery and ruthenium efficiency. Ruthenium efficiency, as used herein, is defined as the yield of RuO₂ deposited divided by the amount of RuO₂ theoretically possible based upon the amount and composition of the precursors. Ideally, the process will optimize the ruthenium efficiency, as the ruthenium containing precursors are relatively expensive precursor materials compared to known glass coating materials.

Where ruthenocene is used as the precursor material, the precursor is preferably sublimed, generally at a temperature of about 120° C. to about 175° C., and carried into the main gas stream over a preheated substrate. In some applications, the substrate may be heated to a temperature of about 550° C. to 650° C., preferably about 625° C. for the deposition of the ruthenium dioxide coating, although the present invention should not be considered limited to this temperature. It is preferred that the deposition take place in the tin bath of the float glass process, but it is also possible, within the scope of the present invention, that the deposition occur in the lehr, or between the lehr and the float bath.

An Increase in the Ru(C₅H₅)₂/O₂ ratio results in metal like Ru non-stoichiometric oxide. It has been found that the addition of water into Ru(C₅H₅)₂/O₂ system can enhance RuO₂ deposition. It has been determined that the presence of water or other oxidant such as EtOAc (ethyl acetate) and IPA (isopropyl alcohol) will not make Ru oxide deposition without presence of oxygen. However, the addition of another oxidant with oxygen will possibly modify the resulting coating, chemically and optically and electrically. The addition of water addition potentially enhances the deposition, but only slightly. It has additionally been found that addition of either ethyl acetate (EtOAc) or isopropyl alcohol (IPA) will result in non-stoichiometric RuO₂, which can exhibit increased sheet resistance.

The method of the present invention is preferably carried out in an on-line, float glass production process, which is well known in the art. An example of such a process can be found in U.S. Pat. No. 5,798,142, which is hereby incorporated by reference as if set forth in its entirety herein. Other known deposition methods may be suitable for use with the present invention.

In a preferred embodiment of the present invention, a heated glass substrate is provided, the substrate having a surface on which the coating is to be deposited. A ruthenium containing precursor, an oxygen containing compound and preferably an inert carrier gas, and optionally water vapor, are directed toward and along the surface to be coated. The mixture is reacted at or near the surface of the glass substrate to form the ruthenium oxide coating. Subsequently, the coated glass substrate is cooled to ambient temperature. Preferably, the inert carrier gas is either helium or nitrogen or a combination thereof. Oxygen gas is the preferred oxygen containing compound for use in the present invention, but it is possible, and within the scope of the present invention, that other oxygen containing materials may be used.

Typically, according to the present invention, growth (deposition) rates of ≧about 130 Å/sec can be achieved in an on-line coater. Theoretically, deposition rates ≧180 Å/sec can be achieved according to the present invention. Generally, in the case of a ruthenium oxide layer, it has been found that the deposited layer can be essentially stoichiometrically pure ruthenium dioxide. The ruthenium oxide coating deposited in accordance with the present invention predominantly exhibits a rutile structure.

The preferred method of deposition, as described above, is through a chemical vapor deposition process, specifically through atmospheric pressure chemical vapor deposition, in an on-line float glass production process. Some possible methods of preparing precursors for use in the CVD process can include the use of a bubbler, as well as solution delivery in conjunction with a thin film evaporator. U.S. Pat. No. 6,521,295 (column 3, line 60 etc.) discloses processes for preparing precursors and is hereby incorporated by reference as if set forth in its entirety herein. In the case of, at least, the ruthenocene precursor, the precursor can be directly sublimed into a vapor.

A ruthenium metal like coating deposited according to the present invention will typically have a resistivity between about 50˜70 μΩ cm. The ruthenium metal like coating is typically has a high concentration of Ru, in excess of 50% and preferably about 60%, and low oxygen, with some carbon incorporation. Grain size of the deposited coating is about 20-50 nm.

The precursor mixture used in the present invention can preferably contain gas phase concentrations of the ruthenium containing precursor in the range of about 0.05% to 2%. Preferably, the ruthenium containing precursor concentration is in the range of about 0.1% to about 1%, and most preferably from about 0.15% to about 0.5%.

Oxygen is preferably present, as expressed in gas phase concentrations, in the amount of about 1 % to about 15%. Preferably, the oxygen is present in the range of from about 1.5% to about 10% and most preferably from about 2.5% to about 7.5%. The remainder of the gas concentration of the precursor mixture is the inert carrier gas and any other material, e.g. water vapor, added to the precursor mixture.

A ruthenium dioxide coating deposited according to the present invention will typically have a resistivity between about 70˜110 μΩ cm. Tested static coater samples of RuO₂ showed Ru/O ratio about 1:2.

The ruthenium dioxide coating deposited according to the present invention preferably has a thickness between about 600 to about 800 angstroms. The thickness can be varied based upon the properties desired.

Ruthenium dioxide coatings deposited in accordance with the present invention, and having the thicknesses noted above (about 600 to about 800 Å), may show resistivities on the order of about 50 to about 90 μΩ cm. To attain similar low emissivity properties for a fluorine doped tin oxide coating would require a coating on the order of about 2500 to about 4500 Å. Thus, a ruthenium dioxide coating may be much thinner yet attain the same desired properties of a much thicker coating of fluorine doped tin oxide.

In addition, it is possible in conjunction with the present invention, to apply a thin ruthenium oxide layer or ruthenium metal like layer to a conventional fluorine doped tin oxide coating stack to further enhance its low E properties. In the case of a ruthenium oxide layer, a layer as thin as 200˜300 Å, can enhance the stack conductivity.

The ruthenium oxide coating on glass substrate provides a coated glass with greatly enhanced solar energy reflection. This is because ruthenium oxide exhibits optical reflection starting from about 650 nm, compared to 1350 nm for SnO₂:F, which effectively reflects NIR energy through coated glass. Additionally, ruthenium oxide is a strongly absorptive material in both the near-infrared and visible spectrums. When using ruthenium oxide in a solar reflective coating stack, solar control performance of Tvis 68% and Tsol 37% can be achieved.

The ruthenium oxide coating on the glass substrate provides a coated glass article having a high visible light transmittance with a reduced total solar energy transmittance when in use in a solar reflective stack. The coated glass article of the invention has a selectivity of 30% or more, the selectivity being defined as the difference between visible light transmittance (Illuminant C) and a total solar energy transmittance on a clear glass substrate at a nominal 3 mm thickness. The selectivity is preferably 30% or more, with a preferred visible light transmittance of 70% or more and a preferred total solar energy transmittance of 40% or less. The use of the inventive coated article in architectural glazings results in a glazing that rejects solar energy in the summer and provides a low U value for the winter.

It is also possible in conjunction with the present invention to provide additional coatings with the ruthenium dioxide and ruthenium metal like coating discussed herein. Coatings may be applied between the ruthenium dioxide or ruthenium metal like coating and the substrate, and/or above the ruthenium dioxide or ruthenium metal like coating. Examples of coatings which may underlay the ruthenium dioxide coating may include, but not be limited to, silica, titania or tin oxide coatings.

In view of the above, a ruthenium dioxide coating produced in accordance with the present invention, can exhibit low resistivity, infrared reflection and absorption, good chemical and thermal durability and stable formation of interfacing with dielectric oxides. Coatings in accordance with the present invention can exhibit improved conductivity to comparable fluorine doped tin oxide coatings and excellent solar control properties. These ruthenium oxide coatings can achieve both low emissivity and solar control properties in a single coating. Additionally, the thinner required coatings are environmentally preferable, and also preferable in terms of production efficiency. RuO₂ coating system uses very low percentage of chemical (for example, about 0.14%) to produce the thin coating required for targeted products which are both preferred in environmental terms.

### Examples

The following examples, which constitute the best mode presently contemplated by the inventors for practicing the present invention, are presented solely for the purpose of further illustrating and disclosing the present invention, and are not to be construed as a limitation on the invention.

With regard to the following tables, for static coater coating: The glass is heated to the desired temperature on a carbon metal block situated inside quartz tube by induction heating source. The ruthenium is delivered by subliming the chemical powder contained in a heated stainless steel bubbler, together with oxygen and nitrogen mixture, passing over the heated glass substrate.

For dynamic coater coating: The chemical delivery is similar to that in static coating process. The glass substrate is pre-heated and moving underneath a coater head where chemical and gas mixture is injected onto the heated moving glass and subsequently extracted.

For static coaters, typical conditions are as follows. The bubbler temperature is typically in the range of about 150-175° C., preferably about 165° C. The N₂ carrier flow is typically about 0.2-1.2 standard liter per minute (slm), preferably about 0.5 slm, with water delivery being about 0.2-1 cc/min, preferably about 0.4 cc/min, O₂ flow being about 1-2 slm, preferably about 2 slm, and N₂ balance flow being about 3-10 slm, preferably about 5 slm. The substrate is typically at a temperature about 600-625° C., preferably about 600° C.

Specific examples are shown in the following tables:

TABLE 1
Static coater examples 1-3

| Example | 1 | | 2 | | 3 | |
|---|---|---|---|---|---|---|
| Coating | Ru metal like | | RuO₂ | | RuO₂ | |
| Substrate | Glass/TiO₂ | | Glass/TiO₂ | | Glass/TiO₂ | |
| Bubbler 1 | Ru(C₅H₅)₂ | | Ru(C₅H₅)₂ | | Ru(C₅H₅)₂ | |
| Temperature | 166° | C. | 166° | C. | 169° | C. |
| N₂ carrier | 1.2 | slm | 0.55 | slm | 0.25 | slm |
| Syringer 1 | Water | | Water | | Water | |
| Flow rate | 0.22 | cc/min | 0.44 | cc/min | 0.83 | cc/min |
| N₂ carrier | 1.0 | slm | 1.0 | slm | 1.0 | slm |
| O_{2 flow} | 2.0 | slm | 2.0 | slm | 2.0 | slm |
| N₂ balance | 3.0 | slm | 5.0 | slm | 10.0 | slm |
| Glass temp | 625° | C. | 625° | C. | 625° | C. |
| Dep. Period | 30 | sec | 45 | sec | 30 | sec |
| Coating | 550 | Å | 830 | Å | 630 | Å |

For conveyor coaters, typical conditions are as follows. The bubbler temperature is typically in the range of about 175-185° C., preferably about 175° C. The He carrier flow is typically about 2-4 slm, preferably about 3 slm, O₂ flow being about 1-2 slm, preferably about 2 slm, and He balance flow being about 35 slm. The substrate is typically at a temperature about 632° C.

TABLE 2
Conveyor coater's example data, Examples 4-7

| Example | 4 | | 5 | | 6 | | 7 | |
|---|---|---|---|---|---|---|---|---|
| Coating | RuO₂ | | RuO₂ | | RuO₂ | | RuO₂ | |
| Substrate | Glass/SnO₂ | | Glass/SnO₂ | | Glass/TiO₂ | | Glass/SnO₂ | |
| Bubbler1 | Ru(C₅H₅)₂ | | Ru(C₅H₅)₂ | | Ru(C₅H₅)₂ | | Ru(C₅H₅)₂ | |
| Temp | 175° | C. | 175° | C. | 180° | C. | 185° | C. |
| N₂ carrier | 3.0 | slm | 2.0 | slm | 3.0 | slm | 3.0 | slm |
| O₂ | 2.0 | slm | 2.0 | slm | 2.0 | slm | 2.0 | slm |
| He balance | 35 | slm | 35 | slm | 35 | slm | 35 | slm |
| Conveyor | 100 | ipm | 100 | ipm | 100 | ipm | 100 | ipm |
| speed | | | | | | | | |
| Glass temp | 632° | C. | 632° | C. | 632° | C. | 632° | C. |
| Coating | 1080 | Å | 840 | Å | 1090 | Å | 960 | Å |
| thickness | | | | | | | | |

TABLE 3
Examples 8-11

| Example | 8 | | 9 | | 10 | | 11 | | 12 | |
|---|---|---|---|---|---|---|---|---|---|---|
| Coating | RuO₂ | | RuO₂ | | RuO₂ | | RuO₂ | | RuO₂ | |
| Substrate | Glass/SnO₂ | | Glass/TiO₂ | | Glass/TiO₂ | | Glass/TiO₂ | | Glass/SnO₂ | |
| Bubbler1 | Ru(C₅H₅)₂ | | Ru(C₅H₅)₂ | | Ru(C₅H₅)₂ | | Ru(C₅H₅)₂ | | Ru(C₅H₅)₂ | |
| Temperature | 175° | C. | 180° | C. | 180° | C. | 180° | C. | 175° | C. |
| He carrier | 3.0 | slm | 4.0 | slm | 4.0 | slm | 4.0 | slm | 5.5 | slm |
| Bubbler 2 | N/A | | N/A | | EtOAc | | IPA | | N/A | |
| Temperature | N/A | | N/A | | 60° | C. | 50° | C. | N/A | |
| He carrier | N/A | | N/A | | 0.3 | slm | 0.5 | slm | N/A | |
| O₂ | 2.0 | slm | 1.0 | slm | 1.0 | slm | 1.0 | slm | 2.0 | slm |
| He balance | 35 | slm | 35 | slm | 35 | slm | 35 | slm | 35 | slm |
| Conveyor | 100 | ipm | 75 | ipm | 75 | ipm | 75 | ipm | 100 | ipm |
| Glass temp | 632° | C. | 632° | C. | 632° | C. | 632° | C. | 632° | C. |
| Coating | 720 | Å | 720 | Å | 700 | Å | 710 | Å | 880 | Å |

In the above tables, ipm = inches per minute

With regard to the above tables, samples 4-6 and 9-10 were tested and indicated that they were primarily ruthenium dioxide, but also contained more than trace amounts of ruthenium metal in the coatings.

Examples of ruthenium dioxide or ruthenium metal like coated glass substrates according to the present invention displayed optical properties as follows, wherein the example numbers refer to the samples from the tables above:

TABLE 4

| Example number | 5 | 9 | 12 |
|---|---|---|---|
| Transmission visible | 37.2% | 31.4% | 38.4% |
| Transmission Color | a* −3.9, | a* −5.4, | a* −4.3, |
| | b* 20.5 | b* 19.6 | b* 20.2 |
| Transmission Solar | 23.4% | 18.5% | 24.3% |
| Reflection visible | 18.3% | 26.2% | 17.7% |
| Reflection color | a* 1.5, | a* −2.4, | a* 1.5, |
| | b* −3.6 | b* 7.4 | b* −2.9 |
| Reflection solar | 28.4% | 35.3% | 26.9% |
| Absorption visible | 44.5% | 42.4% | 43.9% |
| Absorption solar | 48.2% | 46.2% | 48.9% |

In accordance with the provisions of the patent statutes, the present invention has been described in what is considered to represent its preferred embodiment. However, it should be noted that the invention can be practiced otherwise than as specifically illustrated and described without departing from its spirit or scope.

What is claimed is:

1. A method for producing one of a ruthenium dioxide coating or a ruthenium metal like coating on a substrate via a chemical vapor deposition process, comprising:
providing a heated glass substrate having a surface on which the coating is to be deposited;
directing an inert carrier gas, a ruthenium containing precursor and an oxygen containing compound toward and along the surface to be coated; and
reacting the ruthenium containing precursor and the oxygen containing compound at or near the surface of the glass substrate to form a ruthenium dioxide coating or ruthenium metal like coating.

2. The method according to claim 1 wherein the inert carrier gas comprises at least one of helium and nitrogen.

3. The method according to claim 1 wherein the oxygen containing compound is oxygen gas.

4. The method according to claim 1 further comprising providing water vapor with the ruthenium containing precursor and the oxygen containing compound.

5. The method according to claim 1 wherein the ruthenium dioxide layer is deposited at a rate of greater than or equal to about 130 Å/sec.

6. The method according to claim 1 wherein the ruthenium containing precursor is selected from the group consisting of ruthenium carbonyl, ruthenocene, ruthenium tris(tetramethylheptanedionate), and bis(2,2,6,6-tetramethyl-3,5-heptanedionato)(1,5-cyclooctadiene)ruthenium.

7. The method according to claim 6 wherein the ruthenium containing precursor comprises ruthenocene.

8. The method according to claim 1 wherein the ruthenium dioxide coating is deposited at about atmospheric pressure.

9. The method according to claim 1 wherein the ruthenium dioxide coating is deposited at a temperature of about 550° C. to about 650° C.

10. The method according to claim 7 wherein the ruthenocene is sublimed at a temperature between about 120 and about 175° C. prior to being directed toward the surface to be coated.

11. The method according to claim 1 wherein the substrate comprises glass.

12. A method for producing one of a ruthenium dioxide coating or a ruthenium metal like coating on a glass substrate via an atmospheric pressure chemical vapor deposition process, comprising:
providing a heated glass substrate having a surface on which the coating is to be deposited;
directing an inert carrier gas, a ruthenium containing precursor and an oxygen containing compound toward and along the surface to be coated; and
reacting the ruthenium containing precursor and the oxygen containing compound at or near the surface of the glass substrate to form a ruthenium dioxide coating or a ruthenium metal like coating,
wherein the ruthenium containing precursor is selected from the group consisting of ruthenium carbonyl, ruthenocene, ruthenium tris(tetramethylheptadionate), and bis(2,2,6,6-tetramethyl-3,5-heptanedionato)(1,5-cyclooctadiene)ruthenium.

13. A coated article produced by the method according to claim 1.

14. The coated article according to claim 13 wherein the ruthenium dioxide or ruthenium metal-like coating has a thickness of about 600 to about 800 Å.

15. The coated article according to claim 13 wherein the coating is a ruthenium dioxide coating which has a rutile crystalline structure.

16. The coated article according to claim 13 wherein the ruthenium dioxide or ruthenium metal-like coating has a resistivity of about 50 to about 90 μΩcm.

17. The coated article according to claim 13 wherein the coated glass article is a low emissivity glass.

18. The coated article according to claim 13 wherein the coated article is a solar control glass.

19. The coated article according to claim 13 comprising at least one additional coating in addition to the ruthenium dioxide or ruthenium metal-like coating applied over the glass substrate.
